(19) United States
(12) Patent Application Publication
(10) Pub. No.: US 2012/0261740 A1
(43) Pub. Date: Oct. 18, 2012

(54) FLASH MEMORY AND METHOD FOR FABRICATING THE SAME

(75) Inventors: Yimao Cai, Beijing (CN); Ru Huang, Beijing (CN); Shiqiang Qin, Beijing (CN); Poren Tang, Beijing (CN); Shenghu Tan, Beijing (CN)

(73) Assignee: PEKING UNIVERSITY, Beijing (CN)

(21) Appl. No.: 13/389,720

(22) PCT Filed: Oct. 14, 2011
(86) PCT No.: PCT/CN11/80769

§ 371 Date: Feb. 9, 2012

(30) Foreign Application Priority Data
Apr. 13, 2011 (CN) 201110092483.9

(51) Int. Cl. H01L 29/788; H01L 21/336

(52) U.S. Cl. 257/316; 438/151; 257/E29.3; 257/E21.409

(57) ABSTRACT

The present invention discloses a flash memory and a method for fabricating the same, and relates to the technical field of the semiconductor memory. The flash memory includes a buried oxygen layer on which a source terminal, a channel, and a drain terminal are disposed, wherein the channel is between the source terminal and the drain terminal, and a tunneling oxide layer, a polysilicon floating gate, a blocking oxide layer, and a polysilicon control gate are sequentially disposed on the channel, and a thin silicon nitride layer is disposed between the source terminal and the channel. The method includes: 1) performing a shallow trench isolation on a SOI silicon substrate to form an active region; 2) sequentially forming a tunneling oxide layer and a first polysilicon layer on the SOI silicon substrate to form a polysilicon floating gate, and forming a blocking oxide layer and a second polysilicon layer to form a polysilicon control gate; 3) etching the resultant structure to form a gate stack structure; 4) forming a drain terminal at one side of the gate stack structure, etching the silicon film at the other side of the gate stack structure, growing a thin silicon nitride layer, and then refilling the hole structure with silicon material, to form a source terminal. The method has the advantages of high programming efficiency, low power consumption, effectively preventing source-drain punchthrough effect.

The present application claims priority of Chinese Patent Application (No. 201110092483.9), filed on Apr. 13, 2011 with the State Intellectual Property Office of People's Republic of China, which is incorporated herein by reference in its entirety.

### FIELD OF THE INVENTION

The present invention belongs to the technical field of the nonvolatile semiconductor memory in the ultra-large scaled integrated circuit, particularly relates to an improved flash memory based on TFET (Tunneling Filed Effective Transistor) and a method for fabricating the same.

### BACKGROUND OF THE INVENTION

With the rapid development of the semiconductor industry, a variety of consumer electronic products vastly emerge. Serving as an important component of a storage part, nonvolatile semiconductor memories are widely used in the electronic products, and are required more strictly in terms of their performances.

A flash memory is a nonvolatile semiconductor memory widely used. In order to meet the requirement of process of each generation, the flash memory always requires improvements in terms of structure, material, operation mechanism, etc. However, with the continual shrink of process nodes and the emerge of various electronic products with higher performances, more and more requirements are put on the performance of the flash memory in terms of program efficiency, power consumption, device size, etc. Obviously, a conventional memory structure is faced with many challenges, it is necessary to find a new structure to solve these problems.

Among the variety of new-type memories emerged, a flash memory based on TFET is highly concerned due to advantages such as high program efficiency, low power consumption, better suppression ability of source-drain punchthrough effect and so on.

However, limited by the operation mechanism and structure feature, the flash memory based on TEFT also has problems such as a low channel current, a leakage current caused by over-programming.

As for a common structured TFET, there are two operation modes, a P-TFET mode and an N-TFET mode, under different bias conditions for the same device structure. The N-TFET operation mode is a mode in which electrons flow in a channel region of the device when a positive bias voltage is applied to a gate. The P-TFET operation mode is a mode in which holes flow in the channel region of the device when a negative bias voltage is applied to the gate. For this reason, it is necessary to pay an attention to the programming of the flash memory based on TFET, because that excessive electrons are injected into a floating gate due to over-programming so that the entire device is put into the mode of P-TFET by the formed negative potential without applying a gate controlling voltage, thus a leakage current is induced.

Furthermore, the channel current of the flash memory based on TFET is relatively low due to the tunneling mechanism, which influences the application range of the flash memory based on TFET.

For these problems of the current flash memory based on TFET, the present invention provides a new structure to deal with these challenges.

### SUMMARY OF THE INVENTION

For some problems faced by a common flash memory based on TFET, the present invention provides a new structure to increase a channel current, eliminate the problems such as a leakage current induced by over-programming etc, while improving programming efficiency, reducing operation power consumption and effectively preventing a source-drain punchthrough effect.

The technical solution of the present invention is as follow:

A flash memory includes a silicon-on-insulator (SOI) substrate, a source and a drain with different doping types (P+ is the doping type of the source, and N+ is the doping type of the drain), a channel disposed between the source and the drain, a thin silicon nitride layer (between the channel 201 and the source terminal), and a tunneling oxide layer, a polysilicon floating gate, a blocking oxide layer, a polysilicon control gate, sequentially disposed on the channel.

The present invention also provides a method for fabricating the memory mentioned above, includes the following steps.

The shallow trench isolation is performed onto the SOI silicon substrate to form an active region:

1) a silicon dioxide layer (a tunneling oxide layer) and a polysilicon layer are sequentially deposited;

2) a heavily doping is performed to the polysilicon layer to form a floating gate polysilicon;

3) a silicon dioxide layer (i.e. a blocking oxide layer) and a control gate polysilicon layer are further deposited;

4) a heavily doping is performed to the polysilicon layer, and a thermal annealing is performed to activate impurities in the floating polysilicon and the control gate polysilicon;

5) an etching is performed to form a gate stack structure;

6) an N+ implantation is performed to form a drain terminal;

7) an isotropic silicon etching is performed to the other end of the channel, to form a hole structure till a buried oxide;

8) a thin silicon nitride layer is grown on a side adjacent to the channel in the hole structure;

9) the remaining hole structure is filled with silicon, and a P+ dopant implantation is then performed.

The specific operation method of the present invention is briefly described as follow.

When programming, the P+ region is grounded, the N+ region is applied with a positive bias voltage, and the control gate is applied with a positive bias voltage. Under these bias voltages, the device is operated in the N-TFET mode, and the electrons are injected into the floating gate to complete the programming process.

When erasing, the N+ region and the P+ region are applied with positive bias voltages, and the control gate is applied with a negative bias voltage. Under these bias voltages, an FN tunneling will occur, and thus the electrons in the floating gate enter into the substrate to complete the erasion in memory cells.

When reading, the N+ region is applied with a positive bias voltage, the P+ region is grounded, and the control gate is applied with a relatively low positive bias voltage. The setting of the bias voltages requires reading a current from the N+ region without error programming. The current read from the drain terminal (the N+ region) depends on the number of electrons in the floating gate.

As compared with the prior art, the present invention has the following beneficial effects.

The improved flash memory structure based on TFET of the present invention can effectively solve the problems such as low operation current and leakage current caused by over-programming, in addition to having the same features as the common flash memory based on TFET, such as high programming efficiency, low power consumption, suppression to the source-drain punchthrough effect, ideal miniaturization characterics and so on.

Since a thin silicon nitride layer is disposed between the source terminal (P+) and the channel, the heavily doped ions in the P+ region are prevented from diffusing into the channel region, so that the doping concentration gradient between the source terminal and the channel is larger, and the energy band stretching at the interface region becomes more serious, and thus a tunneling is more likely to occur. Thus, under the same bias condition, a higher tunneling current can be obtained and the channel current is improved.

Moreover, for a common flash memory based on TFET, when the electrons are injected into the floating gate, the potential of the floating gate becomes negative. Therefore, when over-programming, if excessive electrons are injected, it is possible that the holes flow through the channel without applying a control gate voltage and the device becomes a P-TFET mode. This causes a leakage current. In the structure mentioned in the present invention, due to presence of the thin silicon nitride layer, the electron current tunneling from the source P+ becomes more, and the hole current from N+ region can be blocked. Therefore, the leakage current can be effectively eliminated, and the power consumption can be further reduced.

### BRIEF DESCRIPTION OF THE DRAWINGS

FIG. 1 is a schematic diagram of the cross-section structure of a common flash memory based on TFET (using a SOI silicon substrate including a buried oxygen layer and a silicon film), in which:

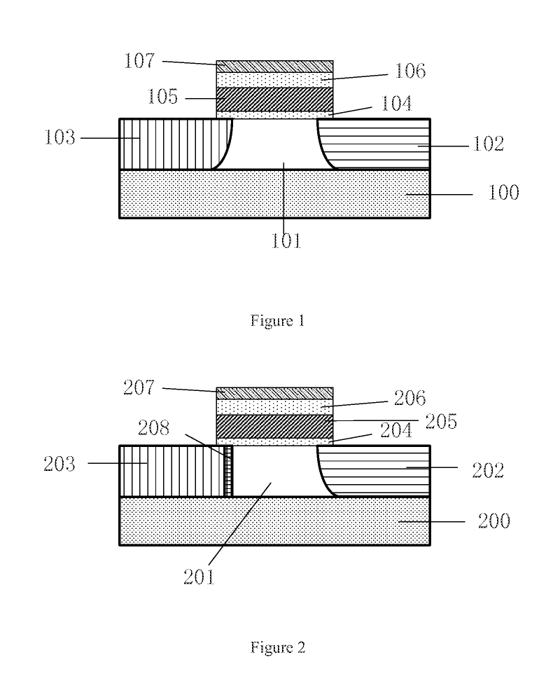

100-a buried oxygen layer; 101-a silicon film; 102-an N+ drain terminal; 103-a P+ source terminal; 104-a tunneling oxide layer; 105-a polysilicon floating gate; 106-a blocking oxide layer; 107-a polysilicon control gate.

FIG. 2 is a schematic diagram of the structure of an improved flash memory based on TFET according to the present invention (using a 301 silicon substrate), in which:

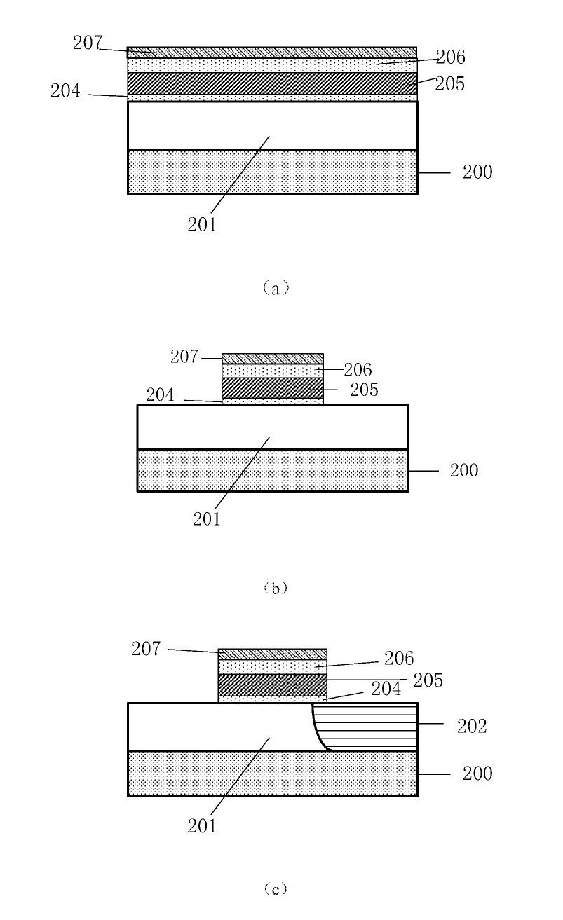

200-a buried oxygen layer; 201-a silicon film; 202-an N+ drain terminal; 203-a P+ source terminal; 204-a tunneling oxide layer; 205-a polysilicon floating gate; 206-a blocking oxide layer; 207-a polysilicon control gate; 208-a thin silicon nitride layer.

FIGS. 3(a)-3(f) are schematic diagrams of the device structure corresponding to respective steps in a process flow for fabricating an improved flash memory based on TFET according to an embodiment of the present invention, in which:

200-a buried oxygen layer; 201-a silicon film; 202-an N+ drain terminal; 203-a P+ source terminal; 204-a tunneling oxide layer; 205-a polysilicon floating gate; 206-a blocking oxide layer; 207-a polysilicon control gate; 208-a thin silicon nitride layer.

### DETAILED DESCRIPTION OF THE EMBODIMENTS

Hereafter, the fabrication of the flash memory of the present invention is further described with reference to the drawings.

The fabrication of the above mentioned flash memory includes the following steps.

1) A SOI silicon substrate is polished, and a shallow trench isolation (STI) is formed.

2) A sacrifice oxide layer is thermally grown to improve the surface quality of a channel, and the sacrifice oxide layer is removed by using hydrofluoric acid. An oxide layer 204 (a tunneling oxide layer) with a thickness of 8 nm is then thermally grown, followed by depositing a polysilicon layer with a thickness of 90 nm, in which a heavily doping is performed and a floating gate structure 205 is formed.

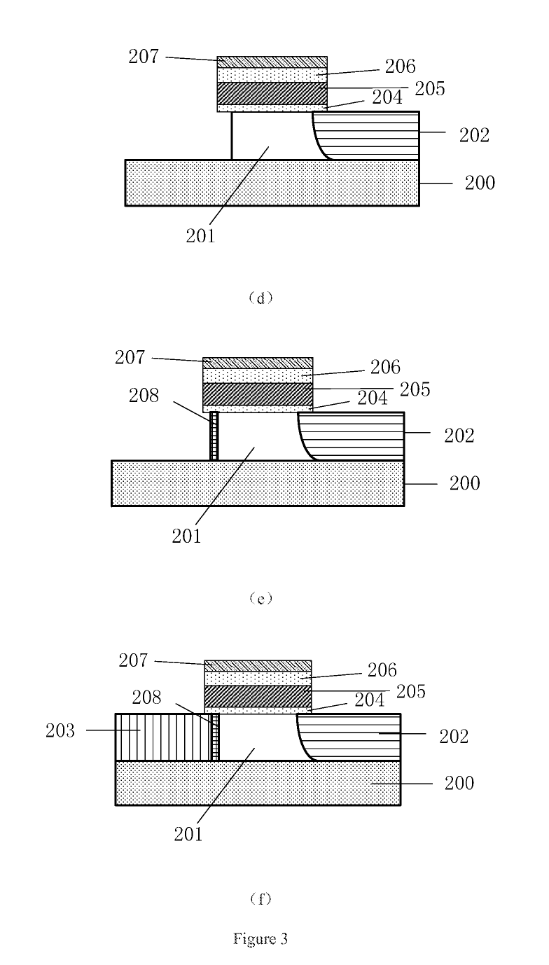

3) Subsequently, an oxide layer 206 (a blocking oxide layer) with a thickness of 10 nm and a polysilicon layer with a thickness of 50 nm are deposited to form a structure as shown in FIG. 3(a).

4) A heavily doing is performed to the polisilicon at the top layer, and then a rapid thermal annealing (RTA) is performed to activate the impurities in a control gate 207 and the floating gate 205.

5) The polysilicon control gate 207, the silicon oxide 206, the polysilicon floating gate 205 and the tunneling oxide layer 204 are etched to form a gate stack structure as shown in FIG. 3(b).

6) Arsenic (As) is implanted into the silicon film at one side of the gate stack structure to form a drain terminal 202 of the device, as shown in FIG. 3(c).

7) Under the protection of a silicon nitride mask, the silicon film at the other side of the gate stack structure is etched by using an isotropic etching method to form a structure as shown in FIG. 3(d).

8) A thin silicon nitride layer 208 with a thickness of about 2 nm is grown at one side adjacent to the channel (i.e. the silicon film 201), as shown in FIG. 3(e).

9) The silicon material is refilled by using an epitaxial method, and boron (B) is implanted to form a source terminal 203 of the device, so that a structure as shown in FIG. 3(f) is formed.

The subsequent steps are all conventional process flow: depositing a low oxygen layer, etching wiring holes, sputtering metal, forming metal lines, alloying, passivating, etc, and finally forming a testable flash memory cell.

1. A flash memory, comprising a buried oxygen layer (200) on which a P+ source terminal (203), a channel (201), and an N+ drain terminal (202) are disposed, wherein the channel (201) is between the P+ source terminal (203) and the N+ drain terminal (202), and a tunneling oxide layer (204), a polysilicon floating gate (205), a blocking oxide layer (206), and a polysilicon control gate (207) are sequentially disposed oh the channel (201), characterized in that, a silicon nitride layer (208) is disposed between the P+ source terminal (203) and the channel (201).

2. The flash memory according to claim 1, characterized in that, the channel (201) is a silicon film, and the tunneling oxide layer (204) is formed of silicon dioxide.

3. A method for fabricating a flash memory, comprising the steps of:
1) performing a shallow trench isolation on a SOI silicon substrate to form an active region
2) sequentially forming a tunneling oxide layer and a first polysilicon layer on the SOI silicon substrate, and heavily doping the first polysilicon layer to form a polysilicon floating gate structure;
3) sequentially forming a blocking oxide layer and a second polysilicon layer on the polysilicon floating gate structure, and heavily doping the second polysilicon layer to form a polysilicon control gate structure;
4) performing a rapid thermal annealing to activate impurities in the first polysilicon layer and the second polysilicon layer, to form a polysilicon floating gate and a polysilicon control gate;
5) etching the polysilicon control gate, the blocking oxide layer, the polysilicon floating gate and the tunneling oxide layer, to form a gate stack structure;
6) forming an N+ drain terminal on the silicon film at one side of the gate stack structure, and etching the silicon film at the other side of the gate stack structure, to forma hole structure to the buried oxygen layer;
7) growing a silicon nitride layer at the side adjacent to the silicon film in the hole structure, and refilling the hole structure with silicon material, to form a P+ source terminal.

4. The method according to claim 3, characterized in that, under the protection of a silicon nitride mask, the silicon film at the other side of the gate stack structure is etched by using an isotropic etching method.

5. The method according to claim 3, characterized in that, a sacrifice oxide layer is thermally grown on the SOI silicon substrate, and after removing the sacrifice oxide layer, the tunneling oxide layer is deposited.

6. The method according to claim 3, characterized in that, the refilling of the hole structure with silicon material is performed by an epitaxial method.

7. The method according to claim 6, characterized in that, the source terminal is formed by implanting B into a refilled silicon film.

8. The method according to claim 6, characterized in, that, the drain terminal is formed by implanting As into the silicon, film.

9. The method according to claim 3, characterized in that, the tunneling oxide layer is grown by using a thermal growth method.
